(19) United States
(12) Patent Application Publication
(10) Pub. No.: US 2023/0282452 A1
(43) Pub. Date: Sep. 7, 2023

(54) CLEANING METHOD, METHOD OF MANUFACTURING SEMICONDUCTOR DEVICE, PLASMA TREATMENT DEVICE, AND OUTER CIRCUMFERENTIAL RING SET

(71) Applicant: KIOXIA CORPORATION, Tokyo (JP)

(72) Inventor: Ryota OHNUKI, Yokkaichi Mie (JP)

(73) Assignee: KIOXIA CORPORATION, Tokyo (JP)

(21) Appl. No.: 17/896,977

(22) Filed: Aug. 26, 2022

(30) Foreign Application Priority Data
Mar. 7, 2022 (JP) 2022-034677

(51) Int. Cl. H01J 37/32; C23C 16/44

(52) U.S. Cl. CPC H01J 37/32642; C23C 16/4405; H01J 37/32862

(57) ABSTRACT

According to one embodiment, a method of cleaning a plasma treatment device that treats a substrate, including conveying a cover ring into a treatment container including an upper electrode in the plasma treatment device. The cover ring is mounted on a substrate mounting table to cover an outer circumferential ring, the substrate mounting table including a lower electrode which faces the upper electrode in the treatment container. In the lower electrode the outer circumferential ring is disposed on a circumferential portion of the substrate mounting table. A cleaning gas is supplied into the treatment container, supplying power to at least one of the upper electrode or the lower electrode. Plasma is generated in the treatment container to clean an inside of the treatment container. The cover ring is conveyed from the treatment container after completion of the cleaning.

### CROSS-REFERENCE TO RELATED APPLICATION

This application is based upon and claims the benefit of priority from Japanese Patent Application No. 2022-034677, filed Mar. 7, 2022, the entire contents of which are incorporated herein by reference.

### FIELD

Embodiments described herein relate generally to a cleaning method, a method of manufacturing a semiconductor device, a plasma treatment device, and an outer circumferential ring set.

### BACKGROUND

In a plasma treatment device that treats a substrate, a member in a treatment container is worn by plasma during the treatment of the substrate and during cleaning of the plasma treatment device. When an outer circumferential ring disposed around the substrate is worn, sheath distortion of plasma occurs such that process characteristics vary.

### DESCRIPTION OF THE DRAWINGS

FIG. 1 is a perspective top view schematically illustrating an example of an overall configuration of a plasma treatment device according to an embodiment.

FIG. 2 is a cross-sectional view schematically illustrating an example of a configuration of a treatment chamber in the plasma treatment device according to the embodiment.

FIGS. 3A and 3B are schematic diagrams illustrating an example of a plasma treatment in the plasma treatment device according to the embodiment.

FIGS. 4A and 4B are schematic diagrams illustrating an example of a cleaning treatment in the plasma treatment device according to the embodiment.

FIG. 5 is a perspective top view schematically illustrating an example of an overall configuration of a plasma treatment device according to a modification example 1 of the embodiment.

FIG. 6 is a half sectional view illustrating a state where a cover ring according to a modification example 2 of the embodiment is disposed on an outer circumferential ring.

FIG. 7 is a half sectional view illustrating a state where a cover ring according to a modification example 3 of the embodiment is disposed on an outer circumferential ring.

### DETAILED DESCRIPTION

Embodiments provide a cleaning method that can reduce the wearing of an outer circumferential ring, a method of manufacturing a semiconductor device, a plasma treatment device, and an outer circumferential ring set.

In general, according to one embodiment, provided is a cleaning method of a plasma treatment device that treats a substrate, the cleaning method including: conveying a cover ring into a treatment container including an upper electrode in the plasma treatment device; mounting the cover ring on a substrate mounting table to cover an outer circumferential ring, the substrate mounting table including a lower electrode which faces the upper electrode in the treatment container and in which the outer circumferential ring is disposed on a circumferential portion; supplying cleaning gas into the treatment container, supplying power to at least any one of the upper electrode and the lower electrode, and generating plasma in the treatment container to clean an inside of the treatment container; and conveying the cover ring from the treatment container after completion of the cleaning.

Hereinafter, an embodiment of the present disclosure will be described in detail with reference to the drawings. The present disclosure is not limited to the following embodiment. In addition, components in the following embodiment include those that are easily conceivable by persons skilled in the art or substantial equivalents thereof.

### Configuration Example of Plasma Treatment Device

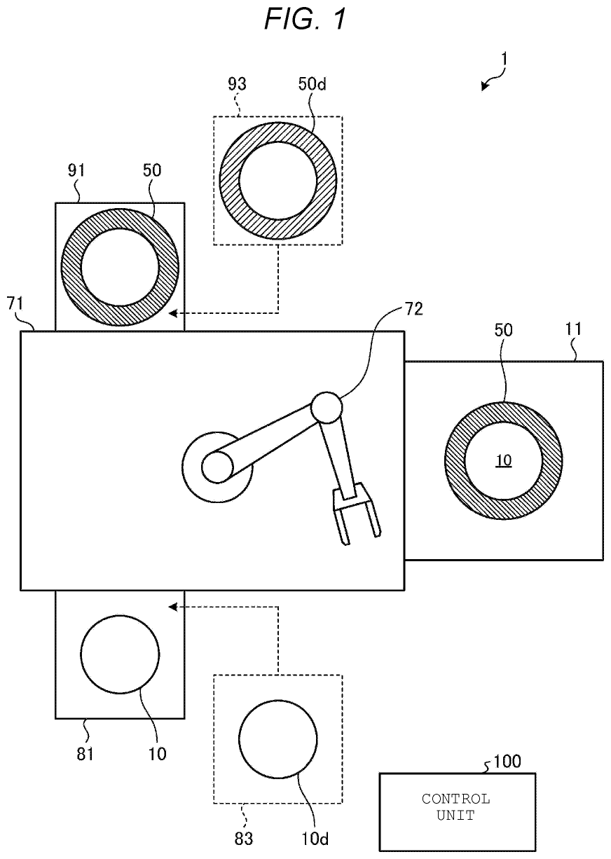

FIG. 1 is a perspective top view schematically illustrating an example of an overall configuration of a plasma treatment device 1 according to the embodiment. As illustrated in FIG. 1, the plasma treatment device 1 includes a treatment chamber 11, a conveyance chamber 71, load locks 81 and 91, and a control unit or controller 100.

The treatment chamber 11 as a treatment container is a container for performing a plasma treatment on a wafer 10 and is connected to the conveyance chamber 71 in a state of being airtightly sealed. The wafer 10 in the treatment chamber 11 is treated with plasma in a state where an outer circumferential ring 50 is disposed on an outer circumference.

The load lock 81 is a container for containing the wafer 10 as a target to be treated and is connected to the conveyance chamber 71 in a state of being airtightly sealed. The load lock 81 is configured to contain a plurality of wafers 10, for example, wafers 10 corresponding to one lot in a state where the wafers 10 are stacked.

In the load lock 81, an accommodation unit 83 for accommodating a dummy wafer 10d that is not a target to be treated is disposed. The accommodation unit 83 is disposed in an upper portion or a lower portion in the load lock 81 at a position overlapping the wafers 10 stacked in the load lock 81 in an up-down direction. The number of dummy wafers 10d that can be accommodated in the accommodation unit 83 may be a given number or less or may be one.

The load lock 91 is a container for containing the outer circumferential ring 50 that is disposed on the outer circumference of the wafer 10 during the plasma treatment, and is connected to the conveyance chamber 71 in a state of being airtightly sealed. The load lock 91 is configured to contain, for example, a plurality of outer circumferential rings 50 in a state where the outer circumferential rings 50 are stacked.

As described below, the outer circumferential ring 50 is configured with some parts including an upper ring. The load lock 91 is configured as, for example, an upper ring container that can contain at least the upper ring among the parts. The plasma treatment device 1 may include a plurality of load locks for the respective parts of the outer circumferential ring 50.

In the load lock 91, an accommodation unit 93 that accommodates a cover ring 50d configured to cover the outer circumferential ring 50 is disposed.

The accommodation unit 93 as the cover ring accommodation unit is disposed in an upper portion or a lower portion in the load lock 91 at a position overlapping the outer circumferential rings 50 stacked in the load lock 91 in the up-down direction. The number of cover rings 50d that can be accommodated in the accommodation unit 93 may be a given number or less or may be one.

The conveyance chamber 71 as a conveyance container is a container for conveying the wafer 10 and the outer circumferential ring 50 in a reduced pressure state and is configured to be airtightly sealed. The conveyance chamber 71 includes a conveyance arm 72 that conveys the wafer 10 and the outer circumferential ring 50.

The conveyance arm 72 conveys the non-treated wafer 10 from the load lock 81 to the treatment chamber 11. In addition, the conveyance arm 72 conveys the treated wafer 10 from the treatment chamber 11 to the load lock 81. In addition, the conveyance arm 72 conveys the dummy wafer 10d from the load lock 81 to the treatment chamber 11, and conveys the dummy wafer 10d from the treatment chamber 11 to the load lock 81.

In addition, the conveyance arm 72 conveys the unused outer circumferential ring 50 from the load lock 91 to the treatment chamber 11. In addition, the conveyance arm 72 conveys the used outer circumferential ring 50 from the treatment chamber 11 to the load lock 91. In addition, the conveyance arm 72 conveys the cover ring 50d from the load lock 91 to the treatment chamber 11, and conveys the cover ring 50d from the treatment chamber 11 to the load lock 91.

In this case, the plasma treatment device 1 may include, separately, a conveyance arm that conveys the wafer 10 and the dummy wafer 10d and a conveyance arm that conveys the outer circumferential ring 50 and the cover ring 50d.

The control unit 100 controls each of the units of the plasma treatment device 1 including the conveyance arm 72. The control unit 100 is configured as a computer including a central processing unit (CPU), a read only memory (ROM), and a random access memory (RAM) (not illustrated).

In this case, the control unit 100 may be configured, for example, as an application specific integrated circuit (ASIC) having a function for the plasma treatment device 1.

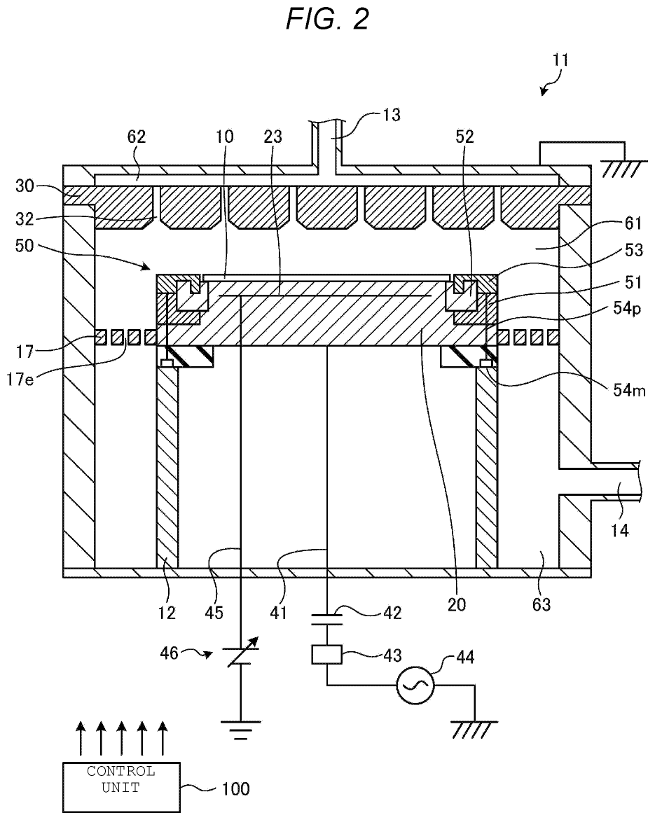

FIG. 2 is a cross-sectional view schematically illustrating an example of a configuration of the treatment chamber 11 in the plasma treatment device 1 according to the embodiment. The treatment chamber 11 is configured such that etching can be performed using plasma, and the plasma treatment device 1 is configured as, for example, a reactive ion etching (RIE) device that etches the wafer 10 as a substrate with plasma.

As illustrated in FIG. 2, the plasma treatment device 1 includes the treatment chamber 11 where the wafer 10 is treated. The treatment chamber 11 is formed of, for example, aluminum and can be airtightly sealed.

In the vicinity of an upper portion of the treatment chamber 11, a gas supply port 13 is provided. A gas supply device (not illustrated) is connected to the gas supply port 13 through a pipe to supply treatment gas used for the plasma treatment. In addition, cleaning gas used for cleaning an inside of the treatment chamber 11 is supplied from the gas supply device.

In the vicinity of the upper portion of the treatment chamber 11 and below the gas supply port 13, a shower head 30 that functions as an upper electrode is provided. In the shower head 30, a plurality of gas flow paths 32 that penetrate the shower head 30 in a plate thickness direction are provided. The treatment gas or the cleaning gas supplied from the gas supply port 13 is introduced into the treatment chamber 11 through the gas flow paths 32.

A wafer stage 20 as the substrate mounting table is disposed below the shower head 30 to face the shower head 30. The wafer stage 20 horizontally supports the wafer 10 as a target to be treated and functions as a lower electrode.

The wafer stage 20 is supported on a support unit 12 that cylindrically protrudes vertically upward from a bottom wall in the vicinity of the center of the treatment chamber 11. The support unit 12 supports the wafer stage 20 to face the shower head 30 in parallel. In addition, the support unit 12 supports the wafer stage 20 to be positioned in the vicinity of the center of the treatment chamber 11 at a predetermined distance from the shower head 30. With this structure, the shower head 30 and the wafer stage 20 configure a pair of parallel plate electrodes.

A feeder 41 that supplies high-frequency power is connected to the wafer stage 20. A blocking capacitor 42, a matching box 43, and a high-frequency power supply 44 are connected to the feeder 41. During the plasma treatment, high-frequency power having a predetermined frequency is supplied from the high-frequency power supply 44 to the wafer stage 20. With this configuration, the plasma treatment device 1 is configured as, for example, a lower application type plasma treatment device.

In this case, the feeder 41 including the blocking capacitor 42, the matching box 43, and the high-frequency power supply 44 may be connected to the shower head 30 functioning as the upper electrode such that the plasma treatment device 1 is configured as an upper application type plasma treatment device.

Alternatively, the feeder 41 including the blocking capacitor 42, the matching box 43, and the high-frequency power supply 44 may be connected to both of the wafer stage 20 and the shower head 30 such that the plasma treatment device 1 is configured as an upper and lower application type plasma treatment device.

In addition, the wafer stage 20 includes a chuck mechanism that electrostatically adsorbs the wafer 10 and also functions as an electrostatic chuck that electrostatically adsorbs the wafer 10.

The chuck mechanism includes a chuck electrode 23, a feeder 45, and a power supply 46. The chuck electrode 23 is built in the wafer stage 20, and the power supply 46 is connected to the chuck electrode 23 through the feeder 45. With this mechanism, direct current power is supplied from the power supply 46 to the chuck electrode 23 such that an upper surface of the wafer stage 20 is electrostatically charged to adsorb the wafer 10.

In a circumferential portion of the wafer stage 20, the outer circumferential ring 50 that covers a side surface and a circumferential portion of the wafer stage 20 is disposed. When the wafer 10 is etched, the outer circumferential ring 50 adjusts an electric field such that the electric field is not deflected with respect to a vertical direction perpendicular to a wafer surface in a circumferential portion of the wafer 10.

The outer circumferential ring 50 is configured with, for example, a plurality of members including a lower ring 51, an intermediate ring 52, and an upper ring 53. Each of the members is formed of, for example, quartz, silicon, silicon carbide, or ceramic.

The members including the lower ring 51, the intermediate ring 52, and the upper ring 53 may be formed of different materials. It is preferable that at least the component of the upper ring 53 is selected depending on the material of the wafer 10 and a material of an etching target film on the surface of the wafer 10. Detailed configurations of these members will be described below.

A pin 54p that penetrates the circumferential portion of the wafer stage 20 and abuts against a lower surface of the upper ring 53 is provided below the outer circumferential ring 50.

The pin 54p is connected to a driving unit 54m such as an actuator including an encoder. By vertically driving the pin 54p using the driving unit 54m, the upper ring 53 is configured to be vertically movable.

The upper ring 53 is supported by a plurality of pins 54p disposed at regular intervals in a circumferential direction of the upper ring 53. The number of pins 54p may be, for example, three or more, and each of the pins 54p includes the driving unit 54m.

A baffle plate 17 is provided between the outer circumferential ring 50 and a side wall of the treatment chamber 11. The baffle plate 17 includes a plurality of gas discharge holes 17e that penetrate the baffle plate 17 in a plate thickness direction.

A gas discharge port 14 is provided in a portion of the treatment chamber 11 lower than the baffle plate 17. A vacuum pump (not illustrated) is connected to the gas discharge port 14 through a pipe.

A region divided by the wafer stage 20 and the baffle plate 17 in the treatment chamber 11 and the shower head 30 is a plasma treatment chamber 61. An upper region in the treatment chamber 11 divided by the shower head 30 is a gas supply chamber 62. A lower region in the treatment chamber 11 divided by the wafer stage 20 and the baffle plate 17 is a gas discharge chamber 63.

During the plasma treatment of the wafer 10, the wafer 10 as a target to be treated is mounted on the wafer stage 20. In addition, the inside of the treatment chamber 11 is evacuated by the vacuum pump (not illustrated) connected to the gas discharge port 14. When the internal pressure of the treatment chamber 11 reaches a predetermined value, the treatment gas is supplied from the gas supply device (not illustrated) to the gas supply chamber 62, and is supplied to the plasma treatment chamber 61 through the gas flow paths 32 of the shower head 30.

In addition, in the lower application type device, in a state where the shower head 30 as the upper electrode is grounded, a high-frequency voltage is applied to the wafer stage 20 as the lower electrode to generate plasma in the plasma treatment chamber 61. On the lower electrode side, a potential gradient is generated between the plasma and the wafer 10 by self-bias by the high-frequency voltage, ions in the plasma are accelerated to the wafer stage 20, and anisotropic etching is performed.

The control unit 100 controls each of the units of the plasma treatment device 1 such as the wafer stage 20, the high-frequency power supply 44, the driving unit 54m, the gas supply device, and the vacuum pump to enable the plasma treatment.

### Example of Plasma Treatment

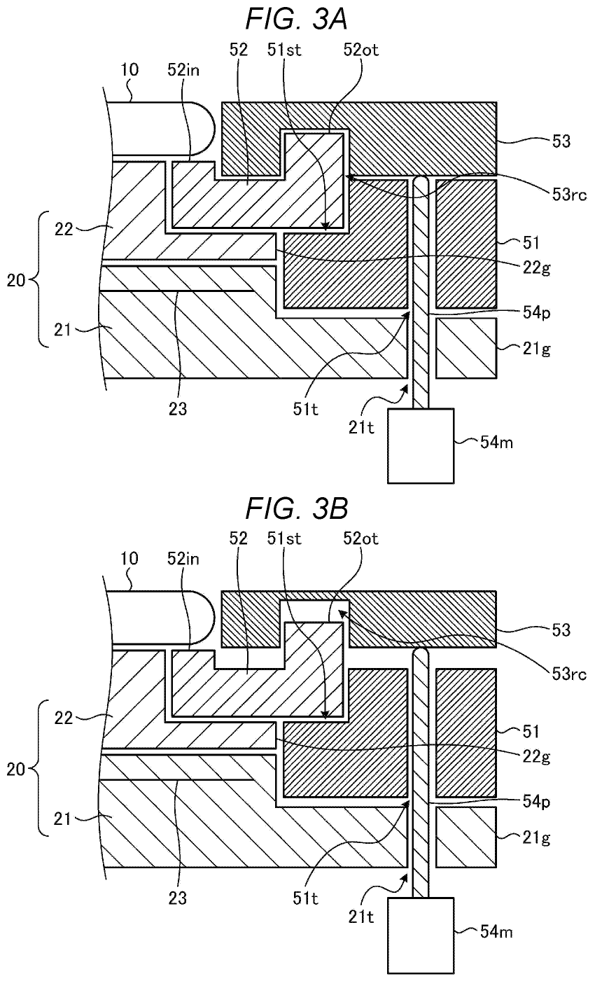

Next, an example of the plasma treatment of the wafer 10 in the plasma treatment device 1 according to the embodiment will be described using FIGS. 3A and 3B. The treatment of the wafer 10 in the plasma treatment device 1 is performed, for example, as a part of steps of manufacturing a semiconductor device.

FIGS. 3A and 3B are schematic diagrams illustrating an example of the plasma treatment in the plasma treatment device 1 according to the embodiment. FIG. 3A is a half sectional view of the outer circumferential ring 50 illustrating an example of the plasma treatment when the outer circumferential ring 50 is in an initial state. FIG. 3B is a half sectional view of the outer circumferential ring 50 illustrating an example of the plasma treatment after the operating time of the outer circumferential ring 50 reaches a predetermined period of time.

As illustrated in FIGS. 3A and 3B, the wafer stage 20 includes: a base material 21 in which the chuck electrode 23 is built; and a ceramic plate 22 on which the wafer 10 is mounted. The base material 21 and the ceramic plate 22 include flange portions 21g and 22g in circumferential portions, respectively. The flange portion 21g of the base material 21 has a through via hole 21t.

By joining the ceramic plate 22 to a center portion of the base material 21, the circumferential portion of the wafer stage 20 includes three stages of level differences where the height increases stepwise toward a center portion of the ceramic plate 22 through the flange portion 21g of the base material 21 positioned on the lowermost portion of the wafer stage 20 and the flange portion 22g of the ceramic plate 22 joined to the base material 21. The outer circumferential ring 50 is disposed along these level differences.

More specifically, as described above, the outer circumferential ring 50 includes the lower ring 51, the intermediate ring 52, and the upper ring 53.

The lower ring 51 is disposed on the circumferential portion of the wafer stage 20 and the flange portion 21g of the base material 21. The lower ring 51 includes a level difference 51st in an inner edge. As a result, in a state where the lower ring 51 is disposed on the flange portion 21g, an upper surface of the inner edge of the lower ring 51 has substantially the same height as an upper surface of the flange portion 22g of the ceramic plate 22. The lower ring 51 includes a through via hole 51t in an outer edge. In a state where the lower ring 51 is disposed on the flange portion 21g, the through via hole 51t of the lower ring 51 is disposed at a position vertically overlapping the through via hole 21t of the flange portion 21g.

The intermediate ring 52 is disposed over the inner edge upper surface of the lower ring 51 and the upper surface of the flange portion 22g of the ceramic plate 22. The intermediate ring 52 has a C-shaped cross-sectional shape where the center portion in the width direction is recessed. That is, the intermediate ring 52 includes protrusions 52in and 52ot in an inner edge and an outer edge, respectively.

In a state where the intermediate ring 52 is disposed on the lower ring 51, an upper surface of a protrusion 52in of an inner edge of the intermediate ring 52 has substantially the same height as an upper surface of a center portion of the ceramic plate 22.

The upper ring 53 is disposed over an upper surface of a center portion of the intermediate ring 52 and an upper surface of an outer edge of the lower ring 51. The upper ring 53 includes a recess portion 53rc on a lower surface, and a protrusion 52ot of an outer edge of the intermediate ring 52 protrudes into the recess portion 53rc of the upper ring 53.

The driving unit 54m is disposed below the circumferential portion of the wafer stage 20. The pin 54p connected to the driving unit 54m abuts against the lower surface of the upper ring 53 through the through via hole 21t of the flange portion 21g of the wafer stage 20 and the through via hole 51t of the lower ring 51.

This way, by combining the plurality of members, the outer circumferential ring 50 covers the circumferential portion of the wafer stage 20 substantially completely. As a result, the circumferential portion of the wafer stage 20 is inhibited from being worn when exposed to plasma.

When the plasma treatment is performed in the treatment chamber 11, a plurality of wafers 10 are conveyed one by one by the conveyance arm 72 from the load lock 81 to the treatment chamber 11 to perform the plasma treatment for a predetermined period of time. The treated wafer 10 is conveyed from the treatment chamber 11 to the load lock 81 by the conveyance arm 72, the next wafer 10 is conveyed into the treatment chamber 11, and the treatment is repeated.

As illustrated in FIG. 3A, when the outer circumferential ring 50 is in an initial state, that is, in a substantially unused state, the pin 54p is disposed on the lowermost side of a movable range of the driving unit 54m. As a result, the upper ring 53 abuts against the upper surface of each of the lower ring 51 and the intermediate ring 52 without being pressed up by the pin 54p.

In a state where each of the members is disposed, the wafer 10 is etched with plasma.

In addition, in the state of FIG. 3A, an upper surface of the upper ring 53 in the initial state has substantially the same height as an upper surface of the wafer 10 mounted on the wafer stage 20. As a result, sheath distortion of plasma in the outer circumference portion of the wafer 10 is inhibited, and ions in the plasma can be made to be substantially vertically incident on the wafer 10.

As illustrated in FIG. 3B, when the outer circumferential ring 50 is continuously used for a predetermined period of time, the upper surface of the upper ring 53 is mainly worn by plasma, and the thickness of the upper ring 53 decreases. When the thickness of the upper ring 53 decreases such that, for example, the upper surface of the upper ring 53 is lower than the height position of the upper surface of the wafer 10, sheath distortion of plasma occurs, and a shape in which the wafer 10 is treated may deviate from a desired shape.

Therefore, the control unit 100 of the plasma treatment device 1 causes the driving unit 54m to drive the pin 54p upward appropriately depending on the operating time of the outer circumferential ring 50 such that the height position of the upper surface of the upper ring 53 is adjusted to be uniform.

More specifically, the control unit 100 stores in advance data regarding the thickness of the upper ring 53, for example, whenever the operating time of the outer circumferential ring 50 reaches a predetermined period of time. Based on this data, the control unit 100 adjusts the height of the upper ring 53 pressed up by the pin 54p whenever the operating time of the outer circumferential ring 50 reaches the predetermined period of time. As a result, the upper surface of the upper ring 53 is maintained at substantially the same height as the upper surface of the wafer 10 mounted on the wafer stage 20, sheath distortion of plasma is inhibited, and the wafer 10 is treated in a desired shape.

The operating time of the outer circumferential ring 50 refers to, for example, a cumulative period of time for which the outer circumferential ring 50 is exposed to plasma. That is, the operating time of the outer circumferential ring 50 is substantially the same as a period of time obtained by multiplying the number of wafers 10 treated after installing the unused outer circumferential ring 50 in the treatment chamber 11 by the treatment time of one wafer 10.

The control unit 100 may manage the height of the upper ring 53 pressed up by the pin 54p based on the cumulative period of time for which the outer circumferential ring 50 is exposed to plasma or based on the number of wafers 10 treated after installing the unused outer circumferential ring 50.

This way, the outer circumferential ring 50 covers the circumferential portion of the wafer stage 20 and inhibits the wafer stage 20 from being worn when exposed to plasma. Accordingly, the outer circumferential ring 50 itself is worn, but the outer circumferential ring 50 is configured to be divided into the plurality of members. Thus, for example, only the upper ring 53 that is most severely worn has to be appropriately replaced, and the replacement frequency of the other members of the outer circumferential ring 50 can be reduced.

In addition, by adjusting the height position of the upper ring 53 with the driving unit 54m and the pin 54p, the lifetime of the upper ring 53 itself can be extended such that replacement frequency can be reduced. The upper ring 53 is replaced when the thickness thereof is less than a thickness that can be adjusted by the driving unit 54m and the pin 54p.

During the replacement of the upper ring 53, the used upper ring 53 is conveyed from the treatment chamber 11 to the load lock 91 by the conveyance arm 72. In addition, one unused upper ring 53 in the load lock 91 is conveyed into the treatment chamber 11 by the conveyance arm 72.

### Example of Cleaning Treatment

Incidentally, as the treatment gas used for etching the wafer 10, halogenated hydrocarbon such as CF₄, CH₃F, C₄F₆, C₄F₈, or C₅F₈ may be used. In this case, when the number of treated wafers 10 increases such that the cumulative plasma application time increases, CF-based deposition is deposited on an inner wall of the treatment chamber 11 and various members in the treatment chamber 11. When the amount of the deposition deposited increases, the deposition functions as a particle source to contaminate the wafer 10.

In the plasma treatment device 1, for example, whenever the cumulative plasma application time exceeds a predetermined period of time, the inside of the treatment chamber 11 is cleaned by plasma generated by the cleaning gas. As the cleaning gas, for example, corrosive gas including halogenated hydrocarbon such as CF₄ or oxidized gas or reducing gas such as oxygen, hydrogen, or carbon dioxide may be used.

When the cumulative plasma application time reaches a predetermined period of time or when the number of treated wafers 10 reaches a predetermined number, the control unit 100 performs the cleaning treatment in the treatment chamber 11.

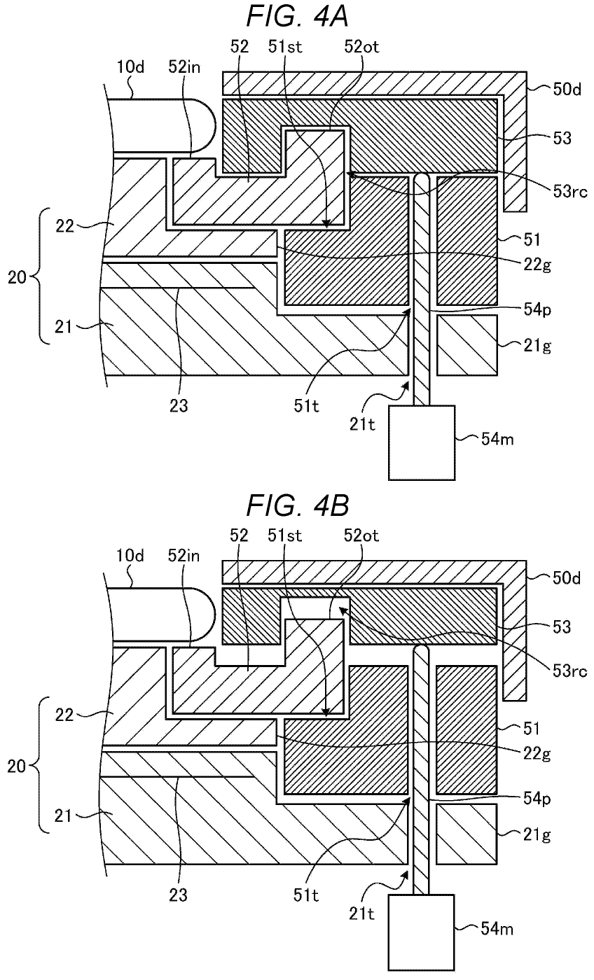

Next, an example of the cleaning treatment of the treatment chamber 11 in the plasma treatment device 1 according to the embodiment will be described using FIGS. 4A and 4B.

FIGS. 4A and 4B are schematic diagrams illustrating an example of the cleaning treatment in the plasma treatment device 1 according to the embodiment. FIG. 4A is a half sectional view of the outer circumferential ring 50 illustrating an example of the cleaning treatment when the outer circumferential ring 50 is in an initial state. FIG. 4B is a half sectional view of the outer circumferential ring 50 illustrating an example of the cleaning treatment after the operating time of the outer circumferential ring 50 reaches a predetermined period of time.

As illustrated in FIGS. 4A and 4B, when the cleaning treatment of the treatment chamber 11 is performed, the dummy wafer 10d that is not a target for the plasma treatment and the cover ring 50d that covers the outer circumferential ring 50 are conveyed into the treatment chamber 11.

The dummy wafer 10d is, for example, a bare silicon wafer, is conveyed by the conveyance arm 72 from the accommodation unit 83 in the load lock 81 containing the wafers 10 as a target to be treated into the treatment chamber 11, and is mounted on the upper surface of the wafer stage 20. As a result, during the cleaning treatment, the ceramic plate 22 of the upper surface of the wafer stage 20 is inhibited from being worn when exposed to plasma of the cleaning gas.

The cover ring 50d is, for example, a resin member or an aluminum member having a coating film such as an aluminum oxide film or an yttria film. Alternatively, the cover ring 50d may be formed of the same member as the upper ring 53, for example, a silicon member, a silicon carbide member, a ceramic member, or a quartz member.

In addition, the cover ring 50d may have, for example, an L-shaped cross-section so as to cover the upper surface and the side surface of the upper ring 53. The cover ring 50d is conveyed by the conveyance arm 72 from the accommodation unit 93 in the load lock 91 containing the unused upper rings 53 into the treatment chamber 11, and is mounted on the upper surface of the upper ring 53.

As a result, the upper surface and the side surface of the upper ring 53 are covered with the cover ring 50d having an L-shaped cross-sectional shape. Accordingly, during the cleaning treatment, the upper ring 53 is inhibited from being worn when exposed to the plasma of the cleaning gas.

In addition, the cover ring 50d has an L-shaped cross-sectional shape and thus can be mounted to be self-aligned on the upper ring 53. As a result, the entirety of the upper ring 53 is covered with the cover ring 50d without requiring a high-precision conveyance operation.

A combination of the outer circumferential ring 50 including the lower ring 51, the intermediate ring 52, and the upper ring 53 with the cover ring 50d will also be referred to as “outer circumferential ring set”.

This way, whenever the cumulative plasma application time reaches a predetermined period of time, the cleaning treatment is performed in a state the upper surface of the wafer stage 20 and the upper surface of the upper ring 53 are covered with the dummy wafer 10d and the cover ring 50d, respectively.

As illustrated in FIG. 4A, when the outer circumferential ring 50 is substantially in the initial state and the upper ring 53 is present at the lowermost position, the cover ring 50d covers the entirety of the upper surface and the side surface of the upper ring 53 and a partial side surface of the lower ring 51.

In addition, the upper surface of the cover ring 50d is present at a position higher than the height of the upper surface of the wafer 10 mounted on the wafer stage 20. When the cover ring 50d is, for example, a conductive member, sheath distortion of plasma may occur in the outer circumference portion of the dummy wafer 10d. However, since this treatment is not for the wafer 10 as a target to be treated, there is no problem.

As illustrated in FIG. 4B, even when the outer circumferential ring 50 is continuously used for a predetermined period of time and the upper ring 53 is present at a position where it is pressed up by the pin 54p, the cover ring 50d covers the entirety of the upper surface and the side surface of the upper ring 53.

In addition, at this time, the upper surface of the cover ring 50d is also present at a position higher than the height of the upper surface of the wafer 10 mounted on the wafer stage 20. As a result, for example, even when sheath distortion of plasma occurs, there is no particular problem as described above.

When the cleaning treatment is completed, the dummy wafer 10d is accommodated again in the accommodation unit 83 in the load lock 81 by the conveyance arm 72, and the cover ring 50d is accommodated again in the accommodation unit 93 in the load lock 91 by the conveyance arm 72, and the dummy wafer 10d and the cover ring 50d are used again for the next cleaning.

The dummy wafer 10d and the cover ring 50d are used only for the cleaning treatment. Therefore, the cumulative time of exposure of these members to plasma increases merely gradually as compared to, for example, the upper ring 53. Thus, the consumption of the dummy wafer 10d and the cover ring 50d are reduced to be small as compared to, for example, the upper ring 53, and the dummy wafer 10d and the cover ring 50d can be repeatedly used for a multiple times of the cleaning treatment as described above.

This way, the wafers 10 as a target to be treated are contained in the load lock 81, for example, in units of lots, and a plurality of upper rings 53 that are more likely to be consumed are contained in the load lock 91. Meanwhile, regarding the dummy wafer 10d and the cover ring 50d, only one item or a given number of items need to be stocked in the plasma treatment device 1. Therefore, the dummy wafer 10d and the cover ring 50d can be stocked in, for example, the load locks 81 and 91, respectively, without preparing dedicated load locks for the dummy wafer 10d and the cover ring 50d.

### Comparative Example

In a plasma treatment device, members in a chamber are worn by plasma. When an outer circumferential ring disposed on an outer circumference of a wafer is worn, sheath distortion of plasma occurs such that process characteristics may vary.

Therefore, various countermeasures are taken, for example, a technique where an outer circumferential ring is configured with a plurality of members to frequently replace only an upper ring that is more likely to be worn or a technique in which a driving unit or the like that presses up an upper ring increases the lifetime of the upper ring.

Meanwhile, the wear of the upper ring progresses even during the cleaning in a treatment chamber that is repeated at predetermined intervals. If the wear of the upper ring during the cleaning can be inhibited, the lifetime of the upper ring can be further extended.

In the cleaning method according to the embodiment, the cover ring 50d is mounted on the wafer stage 20 in the treatment chamber 11 to cover the outer circumferential ring 50, and plasma is generated in the treatment chamber 11 to clean an inside of the treatment chamber 11. As a result, the wear of the outer circumferential ring 50 during the cleaning treatment can be inhibited.

In the plasma treatment device 1 according to the embodiment, the accommodation unit 93 capable of accommodating the cover ring 50d that covers the outer circumferential ring 50 is disposed in the load lock 91 capable of containing the upper rings 53.

As described above, the cover ring 50d can be repeatedly used for multiple times of cleaning treatment, and it is not necessary to stock a large amount of the cover rings 50d in the plasma treatment device 1. Therefore, the accommodation unit 93 that accommodates the cover ring 50d can be provided using a space in the load lock 91.

The outer circumferential ring set according to the embodiment includes; the outer circumferential ring 50 surrounding the circumference of the wafer 10 when the wafer 10 is treated using the plasma treatment device 1; and the cover ring 50d configured to cover the outer circumferential ring 50 when the plasma treatment device 1 is cleaned. As a result, the wear of the outer circumferential ring 50 during the cleaning treatment can be inhibited.

In the outer circumferential ring set according to the embodiment, the cover ring 50d is, for example, a resin member or an aluminum member having a coating film, and the coating film is an aluminum oxide film or an yttria film. As a result, resistance to plasma generated by the cleaning gas such as corrosive gas can be improved, the lifetime of the cover ring 50d can be extended, and the cover ring 50d can be repeatedly used for multiple times of cleaning treatment.

In the outer circumferential ring set according to the embodiment, the cover ring 50d is not limited to the example, and may be a silicon member, a silicon carbide member, a ceramic member, or a quartz member. If the wear of the upper ring 53 can be inhibited, as described above, the cover ring 50d may be formed of the same member as the outer circumferential ring 50 as described above.

In the outer circumferential ring set according to the embodiment, the cover ring 50d has an L-shaped cross-sectional shape that covers the upper surface and the side surface of the outer circumferential ring 50.

As a result, the cover ring 50d can be mounted to be self-aligned on the wafer stage 20 such that the cover ring 50d covers the entirety of the upper surface of the outer circumferential ring 50 without requiring high-precision conveyance. In addition, not only the upper surface but also the side surface of the outer circumferential ring 50 can be protected with the cover ring 50d.

In the plasma treatment device 1 according to the embodiment, a grounding wire that comes into contact with the cover ring 50d mounted on the outer circumferential ring 50 may be provided. As a result, when the cover ring 50d is formed of a conductive member, the cover ring 50d can be grounded, and incidence of ions on the cover ring 50d is inhibited in plasma. Accordingly, the consumption of the cover ring 50d can be further inhibited.

In addition, in the plasma treatment device 1 according to the embodiment, the height of the upper ring 53 is adjusted by the driving unit 54m and the pin 54p. However, the embodiment is not limited to this example. Even in a plasma treatment device not including the driving unit 54m and the pin 54p, the lifetime of the upper ring 53 can be extended using the cover ring 50d.

### Modification Example 1

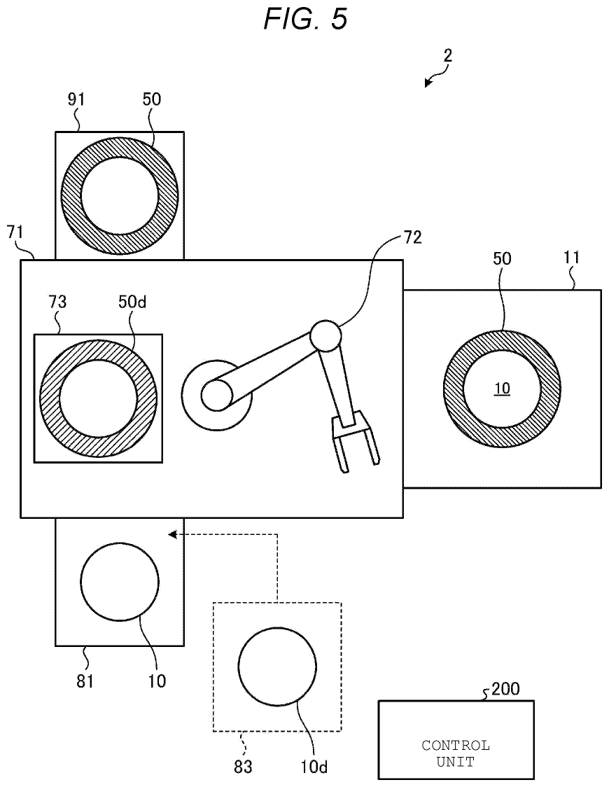

Next, a plasma treatment device 2 according to a modification example 1 of the embodiment will be described using FIG. 5. In the plasma treatment device 2 according to the modification example 1, a place where the cover ring 50d is stocked is different from that of the embodiment.

FIG. 5 is a perspective top view schematically illustrating an example of an overall configuration of the plasma treatment device 2 according to the modification example 1 of the embodiment. In FIG. 5, the same components as those in the plasma treatment device 1 according to the embodiment will be represented by the same reference numerals, and the description thereof will not be repeated.

As illustrated in FIG. 5, in the plasma treatment device 2, an accommodation unit 73 that can accommodate the cover ring 50d is disposed in the conveyance chamber 71 instead of the load lock 91 capable of containing the upper ring 53.

As in the accommodation unit 93 according to the embodiment, the accommodation unit 73 is also configured to accommodate one cover ring 50d or a given number of cover rings 50d. Since only a small number of cover rings 50d needs to be accommodated, the accommodation unit 73 can be disposed using, for example, a space of the conveyance chamber 71.

A control unit or controller 200 in the plasma treatment device 2 controls the conveyance arm 72 to convey the cover ring 50d from the accommodation unit 73 in the conveyance chamber 71 into the treatment chamber 11 during the cleaning treatment and controls the conveyance arm 72 to convey the cover ring 50d from the treatment chamber 11 to the accommodation unit 73 in the conveyance chamber 71 when the cleaning treatment is completed.

In the plasma treatment device 2 according to the modification example 1, the same effect as that of the plasma treatment device 1 according to the embodiment is exhibited.

In the plasma treatment devices 1 and 2 according to the embodiment and the modification example 1, the accommodation unit 83 that accommodates the dummy wafer 10d is disposed in a place different from the accommodation units 93 and 73 that accommodate the cover ring 50d. However, the accommodation unit for the dummy wafer 10d and the accommodation unit for the cover ring 50d may be disposed in the same place, for example, in the conveyance chamber or in the same load lock.

### Modification Example 2

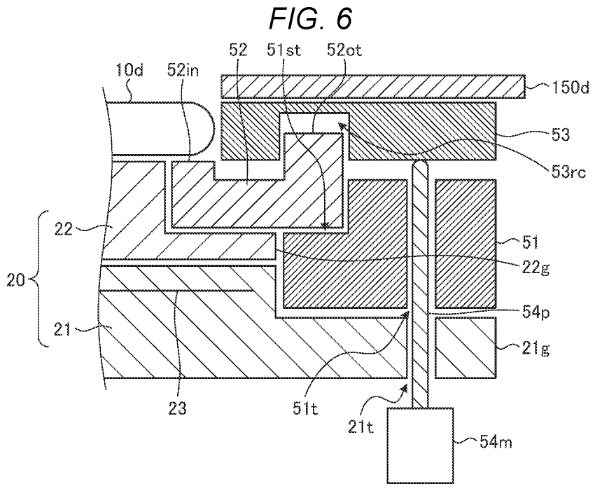

Next, a plasma treatment device according to a modification example 2 of the embodiment will be described using FIG. 6. In the plasma treatment device according to the modification example 2, a shape of a cover ring 150d is different from that of the embodiment.

FIG. 6 is a half sectional view illustrating a state where the cover ring 150d according to the modification example 2 of the embodiment is disposed on the outer circumferential ring 50. In FIG. 6, the same components as those in the plasma treatment device 1 according to the embodiment will be represented by the same reference numerals, and the description thereof will not be repeated.

As illustrated in FIG. 6, the cover ring 150d according to the modification example 2 has a substantially flat cross-sectional shape instead of the L-shaped cross-sectional shape. In addition, the inner diameter of the cover ring 150d is substantially the same as that of the upper ring 53, and the outer diameter of the cover ring 150d is larger than that of the upper ring 53.

Even the cover ring 150d having this shape can protect at least the upper surface that is most likely to be consumed in the upper ring 53. In addition, the outer diameter of the cover ring 150d is configured to be larger than that of the upper ring 53. Therefore, the cover ring 150d can be mounted on the wafer stage 20 such that the cover ring 150d covers the entirety of the upper surface of the upper ring 53 without requiring high-precision conveyance.

In the plasma treatment device according to the modification example 2, the same effect as that of the plasma treatment device 1 according to the embodiment is exhibited.

### Modification Example 3

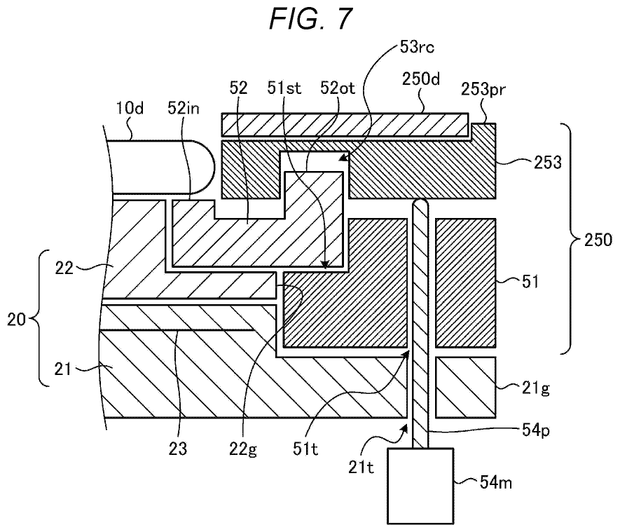

Next, a plasma treatment device according to a modification example 3 of the embodiment will be described using FIG. 7. In the plasma treatment device according to the modification example 3, shapes of an upper ring 253 and a cover ring 250d are different from those of the embodiment.

FIG. 7 is a half sectional view illustrating a state where the cover ring 250d according to the modification example 3 of the embodiment is disposed on an outer circumferential ring 250. In FIG. 7, the same components as those in the plasma treatment device 1 according to the embodiment will be represented by the same reference numerals, and the description thereof will not be repeated.

As illustrated in FIG. 7, the outer circumferential ring 250 according to the modification example 3 includes the upper ring 253 having a different shape from that of the upper ring 53 according to the embodiment. The upper ring 253 according to the modification example 3 includes a protrusion 253pr that is provided in a circumferential portion and protrudes from an upper surface. That is, the upper ring 253 has a shape where an upper surface of an inner side portion is recessed.

The cover ring 250d according to the modification example 3 has a substantially flat cross-sectional shape. In addition, the inner diameter of the cover ring 250d is substantially the same as the inner diameter of the upper ring 253, and the outer diameter of the cover ring 250d is smaller than the outer diameter of the upper ring 253. As a result, the cover ring 250d is mounted on an upper surface of the inner side portion of the upper ring 253 in the protrusion 253pr of the upper ring 253.

When the upper ring 253 and the cover ring 250d have these shapes, substantially the entirety of the upper surface of the upper ring 53 that is most likely to be consumed can be protected.

In addition, the cover ring 250d is mounted to be fitted into the protrusion 253pr of the upper ring 253. As a result, the cover ring 250d can be mounted on the wafer stage 20 such that the cover ring 250d covers the entirety of the upper surface of the inner side portion of the upper ring 253 without requiring high-precision conveyance.

In the plasma treatment device according to the modification example 3, the same effect as that of the plasma treatment device 1 according to the embodiment is exhibited.

### Other Modification Examples

In the embodiment and the modification examples 1 to 3, the plasma treatment device is configured as a RIE device. However, the plasma treatment device is not limited to this configuration. The plasma treatment device may be a device that performs a plasma treatment other than etching, for example, a chemical dry etching (CDE) device or a chemical vapor deposition (CVD) device.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of cleaning a plasma treatment device that treats a substrate, the method comprising:
conveying a cover ring into a treatment container including an upper electrode in the plasma treatment device;
mounting the cover ring on a substrate mounting table to cover an outer circumferential ring, the substrate mounting table including a lower electrode which faces the upper electrode in the treatment container, wherein in the lower electrode the outer circumferential ring is disposed on a circumferential portion of the substrate mounting table;
supplying a cleaning gas into the treatment container, supplying power to at least one of the upper electrode or the lower electrode, and generating plasma in the treatment container to clean an inside of the treatment container; and
conveying the cover ring from the treatment container after completion of the cleaning.

2. The method according to claim 1, wherein the outer circumferential ring includes:
a lower ring mounted on the circumferential portion of the substrate mounting table, and
an upper ring mounted on the lower ring.

3. The method according to claim 1, wherein the cover ring is conveyed from a cover ring accommodation unit into the treatment container.

4. The method according to claim 3, wherein conveying the cover ring into the treatment container comprises:
controlling a conveyance arm to convey the cover ring from the accommodation unit into the treatment container.

5. The method according to claim 3, wherein conveying the cover ring from the treatment container after completion of the cleaning comprises:
controlling the conveyance arm to convey the cover ring from the treatment container into the cover ring accommodation unit.

6. A method of manufacturing a semiconductor device using a plasma treatment device in which the cleaning method according to claim 1 is performed during intervals between treatments of a plurality of substrate, the method comprising:
conveying a first substrate of the plurality of substrates into the treatment container;
mounting the first substrate on the substrate mounting table;
supplying a treatment gas into the treatment container, supplying power to at least one of the upper electrode or the lower electrode, and generating plasma in the treatment container to treat the substrate; and
conveying the substrate from the treatment container after completion of the treatment.

7. The method according to claim 1, wherein the outer circumferential ring includes at least one of quartz, silicon, silicon carbide, or ceramic.

8. The method according to claim 1, wherein the cover ring includes at least one of resin, aluminum, an aluminum oxide film or an yttria film.

9. A plasma treatment device comprising:
a treatment container in which a substrate is treated;
an upper electrode disposed in the treatment container;
a substrate mounting table in which a lower electrode facing the upper electrode is provided and the substrate is mounted;
an outer circumferential ring disposed on a circumferential portion of the substrate mounting table and surrounding a circumference of the substrate;
a power supply configured to supply power to at least one of the upper electrode or the lower electrode to generate plasma in the treatment container; and
a cover ring accommodation unit configured to accommodate a cover ring that covers the outer circumferential ring.

10. The plasma treatment device according to claim 9, wherein the outer circumferential ring includes:
a lower ring mounted on the circumferential portion of the substrate mounting table, and
an upper ring mounted on the lower ring.

11. The plasma treatment device according to claim 9, further comprising a gas supply port configured to supply a cleaning gas into the treatment container, and the power supply is configured to supply power to at least one of the upper electrode or the lower electrode, and generate plasma in the treatment container to clean an inside of the treatment container.

12. The plasma treatment device according to claim 11, further comprising a controller and a conveyance arm,
wherein the controller is configured to control the conveyance arm to convey the cover ring from the accommodation unit into the treatment container.

13. The plasma treatment device according to claim 11, wherein the controller is configured to control the conveyance arm to convey the cover ring from the treatment container into the cover ring accommodation unit after completion of the cleaning.

14. The plasma treatment device according to claim 11, wherein the plasma treatment device is configured to manufacture a semiconductor device by cleaning the inside of the treatment container during intervals between treatments of a plurality of substrate.

15. The plasma treatment device according to claim 9, wherein the outer circumferential ring includes at least one of quartz, silicon, silicon carbide, or ceramic.

16. The plasma treatment device according to claim 9, wherein the cover ring includes at least one of resin, aluminum, an aluminum oxide film or an yttria film.

17. An outer circumferential ring set in a plasma treatment device, comprising:
an outer circumferential ring surrounding a circumference of a substrate; and
a cover ring configured to selectively cover the outer circumferential ring such that the cover ring covers the outer circumferential ring when the plasma treatment device is cleaned and the cover ring does not cover the outer circumferential ring when the substrate is treated using the plasma treatment device.

18. The outer circumferential ring set according to claim 17, wherein the outer circumferential ring includes:
a lower ring mounted on a circumferential portion of a substrate mounting table of the plasma treatment device, and
an upper ring mounted on the lower ring.

19. The outer circumferential ring set according to claim 17, wherein the outer circumferential ring includes at least one of quartz, silicon, silicon carbide, or ceramic.

20. The outer circumferential ring set according to claim 17, wherein the cover ring includes at least one of resin, aluminum, an aluminum oxide film or an yttria film.
